(19) United States
(12) Patent Application Publication
(10) Pub. No.: US 2026/0136711 A1
(43) Pub. Date: May 14, 2026

(54) NUCLEATION LAYER DESIGN FOR THE GROWTH OF INDIUM-CONTAINING GROUP III-NITRIDE-BASED LONG WAVELENGTH EMITTERS

(71) Applicant: Wisconsin Alumni Research Foundation, Madison, WI (US)

(72) Inventors: Guangying Wang, Madison, WI (US); Shubhra S. Pasayat, Middleton, WI (US); Chirag Gupta, Middleton, WI (US); Surjava Sanyal, Madison, WI (US); Shuwen Xie, Madison, WI (US)

(21) Appl. No.: 18/628,039

(22) Filed: Apr. 5, 2024

(51) Int. Cl. H10H 20/812; C30B 25/18; C30B 29/40; H01S 5/343; H10H 20/01; H10H 20/825; H10H 29/24

(52) U.S. Cl. CPC H10H 20/812; C30B 25/186; C30B 29/406; H01S 5/343; H10H 20/0137; H10H 20/825; H10H 29/24

(57) ABSTRACT

Group II-nitride heterostructures that include an In-containing group III-nitride alloy with a high crystal quality for use as buffer layers in light-emitting devices are provided. Also provided are light-emitting devices, such as light-emitting diodes and laser diodes, that incorporate the heterostructures and metal-organic chemical vapor deposition (MOCVD) methods for growing the heterostructures. The heterostructures include a substrate, a thin nucleation layer of an In-containing group III-nitride, a thin cap layer on the nucleation layer, and an In-containing group II-nitride alloy overlayer on the cap layer.

### REFERENCE TO GOVERNMENT RIGHTS

This invention was made with government support under N00014-22-1-2267 awarded by the NAVY/ONR and under 1720415 awarded by the National Science Foundation. The government has certain rights in the invention.

### BACKGROUND

Group III-nitride semiconductors are characterized by the ability to cover a wide emission wavelength range from the deep ultraviolet (UV) to the near infrared (NIR) (i.e., from 6.2 cV to 0.7 eV). InGaN and AlGaN alloys can cover this emission wavelength range by tuning the indium (In) and aluminum (Al) contents in the alloy composition. However, as the In content of an InGaN alloy increases, it becomes more difficult to grow InGaN as a high-quality crystal, and this represents a significant challenge to the fabrication of longer emission light-emitting diodes (LEDs) using InGaN.

One reason it is difficult to grow high-quality In-containing group III-nitride alloys, such as InGaN, with a high In-content InGaN is that In evaporates preferentially at high temperatures. Therefore, low-temperature growth of InGaN is commonly used to maintain a high In content in the alloy. However, low temperature growth is sub-optimal for achieving a high crystal quality, so InGaN grown at low temperatures (e.g., <900° C.) is typically characterized by a high defect density, including a high surface defect density, and a rough surface. As a result, light-emitting active regions grown on the low-quality InGaN have low efficiencies.

Ozaki et al. have attempted to improve the quality of high In content InGaN grown at low-temperatures by growing In_{0.17}Ga_{0.83}N on a conventional GaN-on-sapphire substrate and on a lattice-matched bulk ScAlMgO₄ (SAM) substrate using two-stage metal-organic vapor phase epitaxy (MOVPE) growth. In the first stage, a thin layer of low-temperature InGaN (LT-InGaN) was grown at a temperature less than 700° C., while in a subsequent stage, the growth temperature was ramped up to greater than 800° C. and a thick layer of high-temperature InGaN (HT-InGaN) was grown. However, while some improvement in the In_{0.17}Ga_{0.83}N was seen, further improvements are needed. (See, Ozaki, Takuya, et al. Applied Physics Express 7.9 (2014): 091001.)

### SUMMARY

Group III-nitride-based heterostructures, light-emitting devices that incorporate the group III-nitride-based heterostructures, and methods of making the group III-nitride-based heterostructures are provided.

One embodiment of a group III-nitride-based heterostructure includes: a substrate; an In-containing group III-nitride nucleation layer having a thickness of 100 nm or less on the substrate; a cap layer of AlₓIn_{y}Ga_{1-x-y}N, where 0≤x≤1, 0≤y≤1, 0≤z≤1, the cap layer having a thickness in the range from 1 nm to 100 nm on the In-containing group III-nitride nucleation layer; and optionally, a group III-nitride overlayer over the cap layer.

One embodiment of a light-emitting device includes: a group III-nitride-based heterostructure of a type described herein having an n-type doped group III-nitride overlayer; an active region comprising multiple quantum wells; and a p-type doped group III-nitride layer, wherein the active region is disposed between the n-doped group III-nitride overlayer and the p-doped group III-nitride layer.

One embodiment of a method of making a heterostructure includes the steps of: growing an In-containing group III-nitride nucleation layer having a thickness of 5 nm or less on a substrate at a temperature of 900° C. or lower via metal-organic chemical vapor deposition; growing a cap layer of AlₓIn_{y}Ga_{1-x-y}N, where 0≤x≤1, 0≤y≤1, 0≤z≤1, having a thickness in the range from 1 nm to 5 nm on the In-containing group III-nitride nucleation layer via metal-organic chemical vapor deposition; optionally growing a buffer layer on the cap layer, at a higher temperature than the cap layer; and growing an In-containing group III-nitride overlayer on the cap layer or on the buffer layer.

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings, wherein like numerals denote like elements.

FIG. 1 shows a Group III-nitride heterostructure that includes a substrate, a low-temperature (LT)-In-containing group III-nitride nucleation layer, and a thin GaN cap layer.

FIG. 2 shows a Group III-nitride heterostructure that includes a SAM-on-sapphire substrate, a low-temperature (LT)-In-containing group III-nitride nucleation layer, a thin GaN cap layer, and a high-temperature (HT)-In-containing group III-nitride layer. The MOCVD grown of one such heterostructure in which the In-containing group III-nitride is InGaN and the HT-InGaN is In_{0.17}Ga_{0.83}N is described in the Example.

FIG. 3 shows a Group III-nitride heterostructure that includes a bulk sapphire substrate, a low-temperature (LT)-In-containing group III-nitride nucleation layer, a thin GaN cap layer, and a high-temperature (HT)-In-containing group III-nitride layer. The MOCVD grown of one such heterostructure in which the In-containing group III-nitride is InGaN and the HT-InGaN is In_{0.17}Ga_{0.83}N is described in the Example.

FIG. 4 shows a Group III-nitride heterostructure that includes an n-GaN-on-sapphire substrate, a low-temperature (LT)-In-containing group III-nitride nucleation layer, a thin GaN cap layer, and a high-temperature (HT)-In-containing group III-nitride layer. The MOCVD grown of one such heterostructure in which the In-containing group III-nitride is InGaN and the HT-InGaN is In_{0.095}Ga_{0.905}N is described in the Example.

FIG. 5 is a schematic diagram of an LED that includes a group III-nitride heterostructure with an InGaN nucleation layer and a GaN cap layer.

FIG. 6 is a schematic diagram of a laser diode (LD) that includes a group III-nitride heterostructure with an InGaN nucleation layer and a GaN cap layer.

FIGS. 7A-7C show AFM scans of n-InGaN surfaces for n-InGaN grown via MOCVD on SAM-on-sapphire with InGaN nucleation and GaN cap layers (FIG. 7A), on SAM-on-sapphire without the nucleation and cap layers (FIG. 7B), and on SAM-on-sapphire with the nucleation and cap layers (FIG. 7C).

FIG. 8A shows an AFM scan for a layer of n-InGaN grown on a GaN-on-sapphire substrate using nucleation and cap layers.

FIG. 8B shows an RSM image for the n-InGaN grown on the GaN-on-sapphire substrate using the nucleation and cap layers.

FIG. 8C shows an AFM scan for a layer of n-InGaN grown on a GaN-on-sapphire substrate without nucleation and cap layers.

FIG. 8D shows an RSM image for the n-InGaN grown on the GaN-on-sapphire substrate without the nucleation and cap layers.

FIG. 9 shows a schematic diagram of an LED grown on an SAM-on-sapphire substrate, using nucleation and cap layers.

FIG. 10A shows a schematic diagram of an LED grown on an n-GaN substrate, using nucleation and cap layers.

FIG. 10B shows a schematic diagram of an LED grown on an n-GaN substrate, without nucleation and cap layers.

### DETAILED DESCRIPTION

Group III-nitride heterostructures that include a strain-relaxed In-containing group III-nitride layer with a high crystal quality for use as buffer layers in the fabrication of light-emitting devices are provided. Also provided are light-emitting devices, such as LEDs and LDs, that incorporate the heterostructures and metal-organic chemical vapor deposition (MOCVD) methods for growing the heterostructures. The methods can be used to grow InGaN alloys and other In-containing group III-nitrides with a wide range of In contents; however, the methods are particularly suited for the growth of In-containing group III-nitride buffer layers having a high In content.

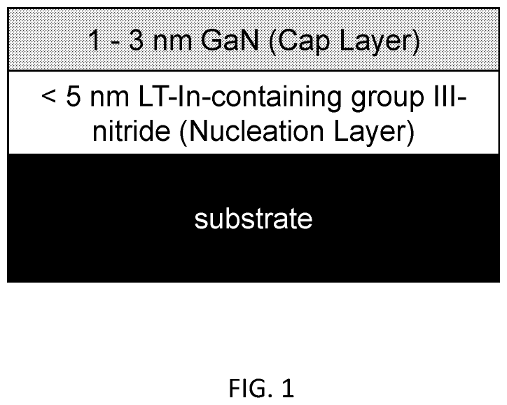

FIG. 1 is a schematic diagram of a group III-nitride heterostructure. The heterostructure includes a substrate upon which a nucleation layer of an indium (In)-containing group III-nitride having a thickness of 100 nm or less (including, for example 10 nm or less and 5 nm or less) is grown and a cap layer of a group III-nitride, such as GaN, having a thickness of 1 nm to 100 nm (including, for example, 1 nm to 5 nm and 1 nm to 3 nm) on the nucleation layer. The nucleation layer is an indium-containing group III-nitride that can be represented by the formula In_{z}Ga_{1-z}N, where 0<z≤1; for alloys where 0<z<1, the alloy is referred to herein as an InGaN alloy.

The heterostructures can be grown using MOCVD growth. The growth substrate should have a lattice constant that is sufficiently close to the lattice constant of the In-containing group III-nitride alloy that is to be grown thereon to enable the growth of a buffer layer of said In-containing group III-nitride alloy with a low defect density and a smooth surface. Therefore, the growth substrate will be selected based on the target composition of the In-containing group III-nitride alloy. Suitable substrates for the growth of high-In-content InGaN (i.e., InₓGa₍₁₋ₓ₎N, where x≥0.1) and other In-containing group III-nitrides, such as Al₍ₓ₋₁₎InₓN, where x≥0.1 or Al_{y}InₓGa_{(1-x-y)}N, where x≥0.1, include SAM-on-sapphire, bulk SAM, GaN-on-sapphire, bulk GaN, bulk sapphire, AlN, AlN-on-sapphire, bulk ZnO, and ZnO-on-sapphire. By way of illustration, In_{0.17}Ga_{0.83}N is lattice-matched with SAM and can be grown on bulk SAM or SAM-on-sapphire. GaN or GaN-on-sapphire can be used to grow InₓGa₍₁₋ₓ₎N, where 0.1≥x≥0.3. (Parker, C. A., et al. Applied Physics Letters 75.17 (1999): 2566-2568.) Other suitable substrates include bulk GaN and SiC.

While the use of SAM substrates may be advantageous due to their lattice match with In_{0.17}Ga_{0.83}N, SAM is expensive. Therefore, substrates comprising a thin overlayer of SAM on a sapphire sublayer may be a more economical option. SAM-on-sapphire substrates with low surface roughness can be fabricated by sputter depositing an amorphous SAM layer on sapphire (0001-oriented Al₂O₃), followed by a thermal anneal to crystallize the SAM. (Wang, Guangying, et al. Crystals 13.3 (2023): 446.)

Deposition of the In-containing group III-nitride on the growth substrate begins with a nucleation layer. Controlling the In content during the nucleation stage of the In-containing group III-nitride growth is key to maintaining a target In concentration in the In-containing group III-nitride of the heterostructure. Therefore, the nucleation layer is grown at a low temperature (“LT”) to minimize or eliminate the preferential evaporation of indium from the alloy. As a result, a high degree of indium incorporation can be achieved during the nucleation stage. Temperatures for the growth of LT-nucleation layers of In-containing group III-nitrides, such as LT-InGaN, are generally no higher than 900° C. and include, for example, temperatures in the range from 400° C. to 900° C., including 600° C. to 800° C.

Next, a thin group III-nitride cap layer is grown on the nucleation layer. This cap layer suppresses the evaporation of volatile In from the nucleation layer during a subsequent higher-temperature (“HT”) In-containing group III-nitride growth stage. The group III-nitride of the cap layer may itself be indium-containing or free of indium. The group III-nitride of the cap layer may be represented by the formula AlₓIn_{y}Ga_{1-x-y}N, where 0≤x≤1 and 0≤y≤1. Thus, the cap layer may comprise, for example, GaN, In_{y}Ga_{1-y}N (0<x<1), or Al_{y}Ga_{1-y}N (0<x<1). The cap layer may be grown at the same or a similar temperature as, or a higher temperature than, the LT-In-containing group III-nitride nucleation layer. Thus, temperatures for the growth of the cap layer include, but are not limited to, temperatures of up to 900° C. For example, temperatures in the range from 400° C. to 900° C. can be used. In some embodiments, the AlₓIn_{y}Ga_{1-x-y}N of the cap layer is grown at a temperature that is 100° C. to 300° C. higher than the temperature used to grow the nucleation layer.

The cap layer is desirably very thin, so that it retains the lattice match, or near lattice match, between the growth substrate and the group III-nitride being grown thereon, but thick enough to avoid removal of the cap layer due to thermal etching during the ramp-up to the higher temperature used to grow an overlayer (e.g., buffer layer) of a HT-group III-nitride layer. For this reason, the cap layer typically has a thickness in the range from 1 nm to 5 nm, including in the range from 1 nm to 3 nm. However, higher thicknesses can be used provided the criteria discussed immediately above are met. The key role of the cap layer is to minimize or prevent the evaporation of In from the In-containing group III-nitride nucleation layer during the subsequent high-temperature growth of a HT-In-containing group III-nitride overlayer. Because the cap prevents In evaporation from the underlying nucleation layer, the nucleation layer can retain its target alloy composition or, if preferential In evaporation occurs to a minor extent, the In content in the nucleation layer may be only slightly decreased. By way of illustration, In_{z}Ga_{1-z}N nucleation layers having an In content in the range from 0.15 to 0.17 can be grown on SAM. However, In_{z}Ga_{1-z}N nucleation layers having an In content outside of this range can also be grown. For example, In_{z}Ga_{1-z}N nucleation layers having an In content in the range from 0.06 to 0.08 can be grown on GaN or GaN-on-sapphire.

The HT group III-nitride is grown on the cap layer at a higher temperature than is used for the growth of the LT-nucleation layer. Temperatures for the growth of the HT-InGaN and other HT-In-containing group III-nitrides are generally greater than 700° C. and include, for example, temperatures in the range from 700° C. to 1300° C., including temperatures in the range from 900° C. to 1000° C. The increased temperature results in a HT-In-containing group III-nitride layer with a high crystal quality and ultra-smooth surface over which a high-quality active layer can be formed. Moreover, because the LT-In-containing group III-nitride nucleation layer is protected from In loss due to evaporation, an HT-indium-containing group III-nitride grown on the cap layer can maintain a high In content and, therefore, serve as a growth substrate for the fabrication of long wavelength LEDs, such as InGaN-based LEDs, including green-emitting, yellow-emitting, and red-emitting LEDs and yellow-emitting LDs.

The HT group III-nitride overlayer is grown to a thickness that provides the desired degree of strain relaxation for its intended application and emission wavelength. Therefore, the thickness of the HT-In-containing group III-nitride will depend on the requirements of the device into which it will be incorporated. However, because defect density tends to increase with increasing HT-In-containing group III-nitride thickness, it may be desirable to grow the heterostructure on a lattice-matched substrate, such as SAM, to reduce compressive strain in the heterostructure and enable the growth of strain-free (100% relaxed) In-containing group III-nitride.

To render the HT-In-containing group III-nitride suitable for use as the n-type layer in a light-emitting device or a cladding layer in a laser, it can be doped with n-type dopants (e.g., Si) during MOCVD growth using known techniques, as illustrated in the Example.

Optionally, a buffer layer can be grown on the cap layer. Typically, the buffer layer will have have the same composition as the cap layer, but a different group III-nitride could also be used. For example, a GaN buffer layer can be grown on a GaN cap layer, prior to the growth of an HT-indium-containing group III-nitride overlayer. The buffer layer is grown at a high temperature, such as a temperature that is close to or the same as the temperature used to grow the HT-In-containing group III nitride overlayer. As a result, the buffer layer has a lower dislocation defect density than its underlying cap layer, which is grown at a lower temperature, and facilitates the epitaxial growth of the HT-In-containing group III nitride overlayer with a high crystal quality. If present, the buffer layer typically has a thickness of 10 nm or lower—for example, a thickness in the range from 2 nm to 10 nm or from 5 nm to 10 nm. Because the HT-buffer layer is characterized by a lower defect density than its LT-cap layer, the two layers can be distinguished in transmission electron microcopy images of the heterostructures, where the interface between the LT-cap layer and the HT-buffer layer will be delineated in the image. While the buffer layer is omitted in the structures of some of the accompanying drawings, it should be understood than in some embodiments of the heterostructures shown in these figures, an HT-buffer layer having the same chemical composition as the cap layer can be present between said cap layer and the HT-indium-containing group III-nitride overlayer.

The inclusion of the cap layer in the heterostructure results in an overlying HT-In-containing group III-nitride layer having a higher crystal quality than an HT-In-containing group III-nitride layer grown using the same MOCVD growth conditions, but lacking the cap layer. For the purposes of conducting a crystal quality comparison, atomic force microscopy (AFM) measurement can be taken over a surface area of 1 μm×1 μm to determine the rms roughness of the alloy surface. The inclusion of the cap layer in the heterostructures enables the growth of group III-nitride layers having a rms surface roughness of less than 30 nm, less than 20 nm, less than 15 nm, less than 12 nm, less than 10 nm, or less than 5 nm. These group III-nitride layers may be strain-relaxed. By way of illustration only, stain-relaxed In_{0.17}Ga_{0.83}N layers with a thickness in the range from 100 nm to 500 nm can be grown over SAM or on SAM-on-sapphire with a rms surface roughness in the range from 10 nm to 15 nm or even lower. The inclusion of the cap layer can also be used to increase the In content in a HT-In-containing group III-nitride overlayer relative to the In content in an HT-In-containing group III-nitride layer grown using the same MOCVD growth conditions, but lacking the cap layer. Notably, these improvements in crystal quality and/or enhanced In content can be achieved even when the HT-In-containing group III-nitride grown on the cap layer (or, if present, on an HT-buffer layer) has a significantly higher thickness than the same HT-In-containing group III-nitride grown in the absence of the cap layer. By way of illustration, using the cap layer, lower surface roughness, and/or increased In content may be achieved even for an HT-indium-containing group III-nitride overlayer having a thickness that is at least twice the thickness of an HT-indium-containing group III-nitride overlayer grown in the absence of the GaN cap layer.

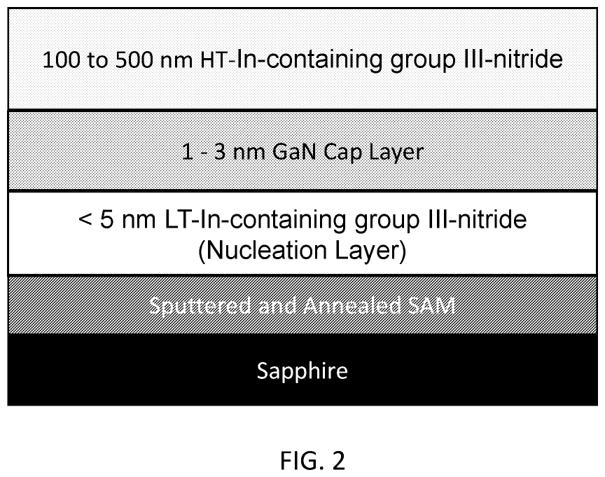

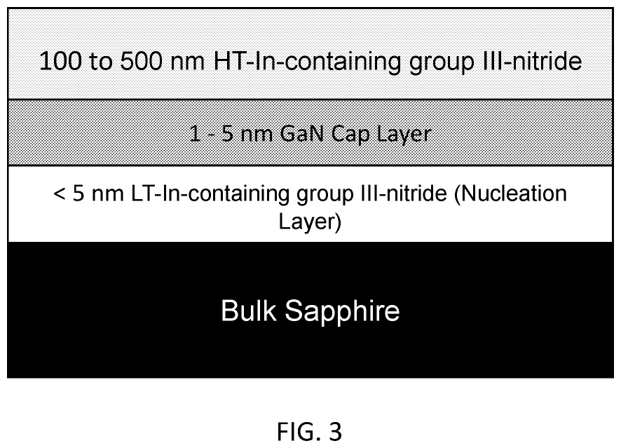

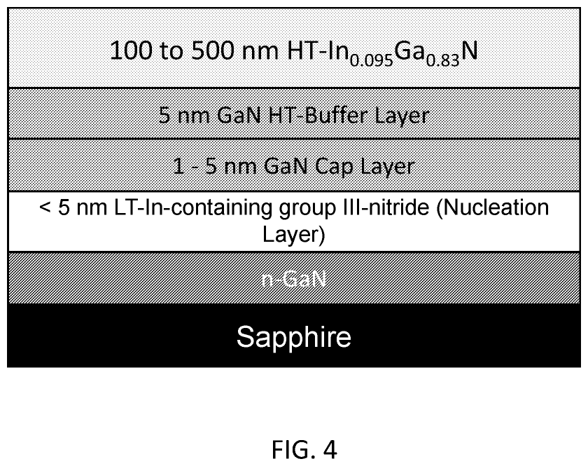

Numerous group III-nitride heterostructures can be grown in accordance with the description provided above. Three illustrative examples of such heterostructures are shown schematically in FIGS. 2-4.

In some variations on the group III-nitride heterostructures, the nucleation layer comprises two or more different nucleation sub-layers having different compositions, wherein each nucleation sub-layer meets the description of a nucleation layer provided above and/or the cap layer comprises two or more different cap sub-layers having different compositions, wherein each cap sub-layer meets the description of a cap layer provided above.

In some variations on the group III-nitride heterostructures, the cap layer comprises two or more different cap sub-layers that have the same or different compositions, but that are grown at different temperatures, wherein each cap sub-layer meets the description of a cap layer provided above. In some such embodiments, the cap sublayers are grown at successively higher temperatures.

When nucleation sub-layers are present in the group III-nitride heterostructures, the combined thickness of the nucleation sub-layers may be in the range of the thickness of a single nucleation layer, as described above, and the thickness of each sub-layer making up the nucleation layer may be the same or different. Similarly, when cap sub-layers are present in the group III-nitride heterostructures, the combined thickness of the cap sub-layers may be in the range of the thickness of a single cap layer as described above, and the thickness of each sub-layer making up the cap layer may be the same or different.

Each of the layers, including nucleation sub-layers and cap sub-layers, in the group III-nitride heterostructures may be n-doped, p-doped, or unintentionally doped (UID) and may be grown with an In-surfactant. The dopant concentrations in two or more doped group III-nitride layers may be differ between said layers. One or more of the layers may be semi-insulating.

### Light-Emitting Devices.

The group III-nitride heterostructures described herein can be used to fabricate LEDs, including μLEDs having chip dimensions below 100 μm, and LDs that emit at wavelengths from the deep UV through the near IR, including green-emitting LEDs and yellow-emitting LDs.

In the light-emitting devices, carriers (electrons and holes) are injected into an active region comprising multiple quantum wells (MQWs) under the influence of an electric field applied across the device heterostructure. In the active region, the carriers recombine to emit photons. In addition to the active region, the devices include two or more electrically conductive contacts positioned to apply the electric field across the heterostructure, including across the MQWs in the active region, and a voltage source coupled to the electrically conductive contacts to apply a voltage difference between the contacts, thereby generating the electric field. Electrically conductive contacts that are positioned to apply an electric field across the active region when the light-emitting device is in operation are referred to as being in electrical communication with the active region. However, the electrically conductive contacts need not be in direct physical contact with the active region; they may be separated from the active region by one or more additional device layers.

### LEDs.

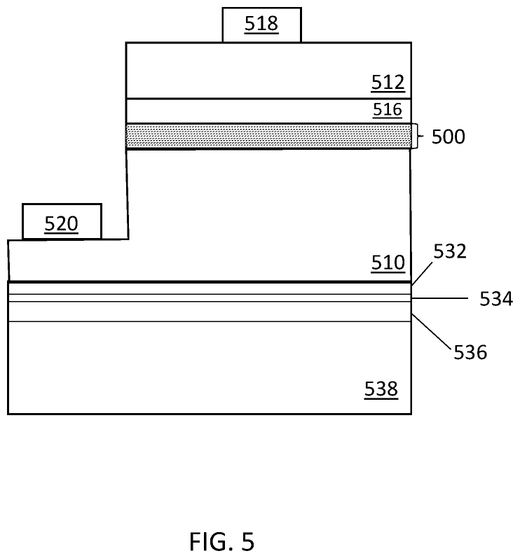

FIG. 5 is a schematic diagram of a heterostructure for an LED. In the LED, an active region having an MQW structure 500 is disposed between an electron-injection layer 510 comprising an n-type semiconductor and a hole-injection layer 512 comprising a p-type doped semiconductor. Optionally, an electron-blocking layer (EBL) 516 comprising a p-type semiconductor having a higher bandgap than the p-type doped semiconductor of hole-injection layer 512 may be disposed between hole-injection layer 512 and active region 500 to avoid leakage of electrons into the p-type doped semiconductor. Electron-injection layer 510, hole-injection layer 512, and EBL 516 may be made from various group III-nitride semiconductors.

A group III-nitride heterostructure is integrated into the LED, wherein the electron-injection layer 510 is provided by a strain-relaxed, n-type doped HT-In-containing group III-nitride (e.g., InGaN) layer 510, on a cap layer 532 (e.g., GaN), on an LT-In-containing group III-nitride (e.g., InGaN) nucleation layer 534 on a growth substrate. In the embodiment of the LED shown in FIG. 5, the growth substrate is SAM (536)-on-bulk sapphire (538).

During operation of the LED, a forward bias is applied using an electrically conducting (typically metallic) p-contact 518 on hole-injection layer 512 and an electrically conducting (typically metallic) n-contact 520 on electron-injection layer 510. This applied bias causes electrons from the electron-injection layer and holes from the hole-injection layer to flow to the active region 500, where they are captured by quantum wells and recombine to generate light. Suitable p-type doped semiconductors for the hole-injection and electron-blocking layers include, but are not limited to, Mg-doped InGaN; suitable n-type doped semiconductors for the electron-injection layer include Si-doped InGaN or Si-doped AlInGaN; and suitable semiconductors for the MQW structure include InGaN/AlGaN/GaN.

The LEDs may be grown on a LED substrate of the same or different wavelength absorption/emission properties and arrays of the LEDs may be mesa etched to enable individual contact exposure.

The LED devices fabricated over the nucleation layer and cap layer of the heterostructures include LED arrays that include a plurality of LEDs. For example, an LED array may include at least three individual LEDs, such as a red, a green and a blue LED, which may or may not be connected by tunnel junctions. In some such embodiments, the LEDs in the array are mesa etched to expose individual contacts to render them independently addressable.

### LDs.

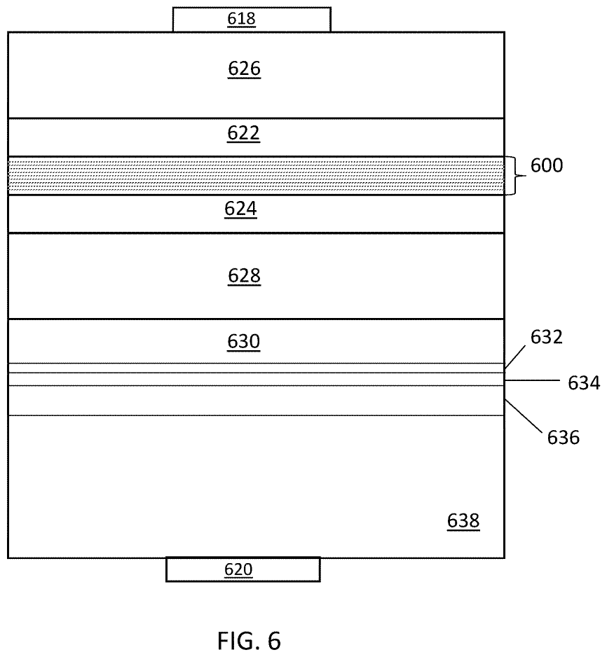

FIG. 6 is a schematic diagram of an LD. In the LD, the active region 600 is disposed between a first waveguide layer 622 comprising a p-type doped or undoped group III-nitride semiconductor and a second waveguide layer 624 that is disposed opposite first waveguide layer 622 and comprises an undoped or n-type doped group III-nitride semiconductor. A first cladding layer 626 comprising a p-type doped group III-nitride semiconductor is disposed over first waveguide layer 622 and a second cladding layer 628 comprising an n-type doped group III-nitride semiconductor is disposed below second waveguide layer 624 and opposite first cladding layer 626. Optionally, an EBL comprising a p-type doped group III-nitride semiconductor can be inserted between first waveguide layer 622 and first cladding layer 626 or between the MQW active region 600 and first waveguide layer 622. The waveguide layers are characterized in that they are more lightly-doped than their respective cladding layers.

Second cladding layer 628 is grown on a group III-nitride heterostructure that includes a strain-relaxed, n-type doped HT-In-containing group III-nitride (e.g., InGaN) buffer layer 630, cap layer 632 (e.g., GaN) and LT-In-containing group III-nitride (e.g., InGaN) nucleation layer 634 on a growth substrate. In the embodiment of the LED shown in FIG. 6, the growth substrate is SAM (636)-on-bulk sapphire (638). Optionally, an electron-blocking layer (EBL) (not shown) comprising a p-type semiconductor having a higher bandgap than the first waveguide layer 622 may be disposed between first waveguide layer 622 and active region 610.

Suitable materials for the various layers of the LD shown in FIG. 6 include, but are not limited to: waveguide layers (622, 624)—InGaN or GaN; p-cladding (626)—InGaN (with a lower In content than the waveguide), preferably GaN, AlGaN, AlInGaN; n-cladding (628)—InGaN (with lower In content than the waveguide), preferably GaN, AlGaN, AlInGaN, and closely lattice matched to the HT InGaN layer (630); and active region (600)-InGaN/AlGaN/GaN.

The LDs may be grown on a LD substrate of the same or different wavelength absorption/emission properties and arrays of the LDs may be mesa etched to enable individual contact exposure.

### Device Fabrication.

The group III-nitride layers in the heterostructures and light-emitting devices, including the active region, can be grown using vapor deposition methods, such as MOCVD, plasma chemical vapor deposition (CVD), or hot-filament CVD, or by molecular beam epitaxy (MBE). The metal contacts can be deposited by metal deposition techniques, such as atomic layer deposition (ALD), sputtering, or evaporation. Various metals, metal alloys, and electrically conducting oxides can be used to form electrically conducting contacts. By way of illustration only, contacts can be composed of gold, platinum, chromium, tungsten, titanium, aluminum, nickel, gold, or alloys thereof.

If the growth of the heterostructure utilizes MBE, growth may take place in a vacuum chamber in which a growth substrate typically is supported on a rotatable platform. A heat source (e.g., a resistive heater) in thermal communication with the growing heterostructure can be used to tailor the growth temperature for each of the various material layers to provide high-quality crystal growth.

Epitaxial growth using vapor deposition is carried out by exposing the substrate or the previously grown layer of the heterostructure to metal-containing and nitrogen-containing precursor molecules that decompose and react to form the various layers. These precursors may be introduced into the vacuum chamber with a carrier gas, such as hydrogen (H₂) or nitrogen (N₂). For MOCVD growth, the precursors are metal-organic compounds, such as trimethyl gallium (TMGa), triethyl gallium (TEGa), trimethyl aluminum (TMAl), triethyl aluminum (TEAl), trimethyl indium (TMI), and triethyl indium (TEI). Ammonia (NH₃) is typically used as a nitrogen precursor molecule. For the growth of doped semiconductors, a dopant-containing precursor (e.g., silane (SiH₄) for Si doping or magnesocene (bis (cyclopentadienyl) magnesium (Cp₂Mg)) for Mg doping) is also introduced into the chamber. An indium surfactant may be used during MOCVD growth.

By adjusting the carrier gases, precursor gas flow rates, pressures, growth temperature, or a combination thereof during the growth of a material layer, high quality crystal layers with precisely tailored material properties can be grown.

### Examples

### Example 1: LED Grown on Sapphire or SAM-On-Sapphire

This example illustrates the fabrication of LEDs in which the active layers are grown on a heterostructure that includes an InGaN nucleation layer, a GaN cap layer on the InGaN nucleation layer, and a strain-relaxed InGaN layer on the GaN nucleation layer. In these studies, bulk sapphire, SAM-on-sapphire, and GaN-on-sapphire were investigated as substrates. The GaN-on-sapphire wafers were purchased from Enkris Semiconductors.

While this application focuses on the growth of LEDs based on InGaN heterostructures, it should be understood that the processes and processing conditions described herein are applicable to other In-containing group III-nitrides.

For purposes of comparison, heterostructures were grown with and without an InGaN nucleation layer and GaN cap layer. In the embodiments that included the nucleation and cap layers, a thin (3 nm-thick) nucleation layer of InGaN was grown on each substrate via MOCVD using TEGa, TMIn, and NH₃ as the precursor gasses and N₂ as a carrier gas. A thinner (1 nm-thick) cap layer of GaN was then grown on the nucleation layer via MOCVD using TEGa and NH₃ as the precursor gases and N₂ as a carrier gas. The nucleation layer was grown at low temperature (<900° C.; using a set point of 662° C.).

A strain-relaxed layer of n-InGaN (Si-doped InGaN) was grown on the GaN cap layer or, for the comparative samples, on the substrates. The growth temperature was 920° C. and SiH₄ was used as the dopant precursor with a target dopant concentration of 5e18. When the nucleation and cap layers were present, a high-quality layer of the n-InGaN was grown to a thickness of 330 nm on the SAM-on-sapphire, the bulk sapphire, and the GaN-on-sapphire substrates. However, when the nucleation and cap layers were absent, the n-InGaN was grown to a thickness of only 150 nm.

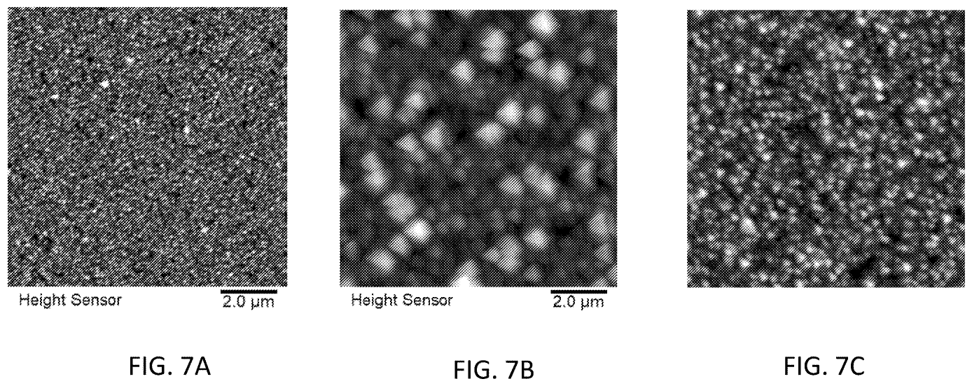

AFM scans of the n-InGaN surfaces were used to determine surface roughness. The scans are presented in FIGS. 7A, 7B, and 7C for n-InGaN on SAM-on-sapphire with the nucleation and cap layers, n-InGaN on SAM-on-sapphire without the nucleation and cap layers, and n-InGaN on SAM-on-sapphire with the nucleation and cap layers using a different scan size, respectively. The n-InGaN grown on SAM-on-sapphire has a surface roughness of 11.7 nm and 10.3 nm over a surface area of 10 μm×10 μm on a 1 μm and a 3 μm scale, respectively. This was considerably lower than the 64.1 nm (over a 2 μm×2 μm surface area) for the n-InGaN grown on SAM-on-sapphire without the nucleation and cap layers. The surface roughness was comparable to that reported for an n-InGaN grown on bulk SAM without a GaN cap layer. However, in that report, the smooth n-InGaN layer had a much lower thickness (˜150 nm) (see. T. Ozaki et al. APEX. 7 091001 (2014)).

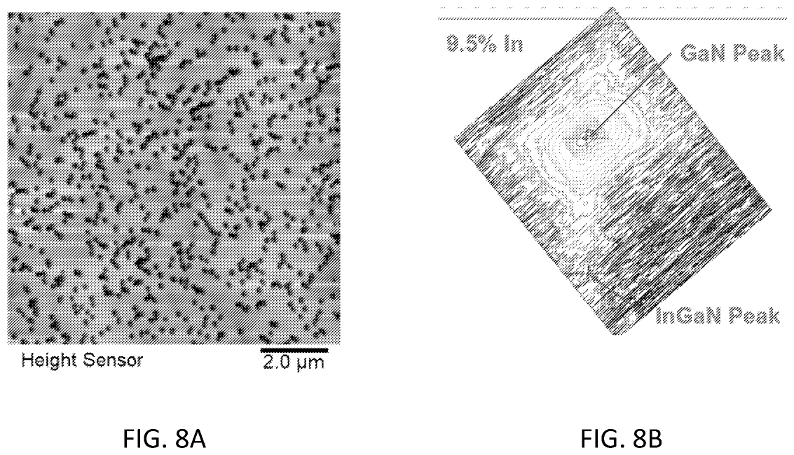

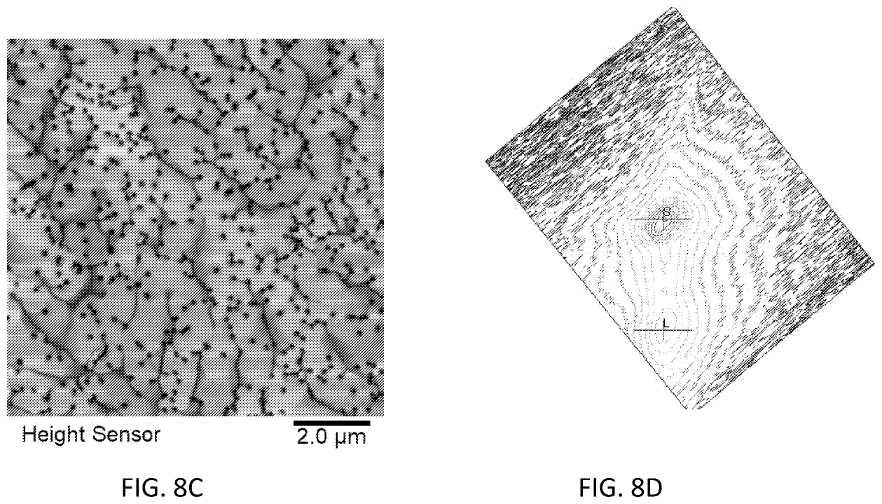

An AFM scan for the n-InGaN (˜330 nm-thick) grown on a GaN-on-sapphire substrate (GaN layer thickness=3 μm) using the nucleation and cap layers is shown in FIG. 8A, revealing a surface roughness of 5.3 nm, which compares very favorably with the 104 nm surface roughness previously reported for a 150-nm thick n-InGaN grown on GaN-on-sapphire without a GaN cap layer (see, T. Ozaki et al. APEX. 7 091001 (2014)). An RSM image for the n-InGaN grown on the GaN-on-sapphire substrate using the nucleation and cap layers is shown in FIG. 8B and demonstrates that an In content of 0.095 was achieved in the n-InGaN. For comparison, an AFM scan for n-InGaN (˜330 nm-thick) grown on a GaN-on-Sapphire substrate (GaN layer thickness=3 μm) without the nucleation and cap layers is shown in FIG. 8C, revealing a surface roughness of 8.3 nm. The corresponding RSM image for the n-InGaN grown on the GaN-on-sapphire substrate without the nucleation and cap layers is shown in FIG. 8D and demonstrates that an In content of only 0.07 was achieved in the n-InGaN.

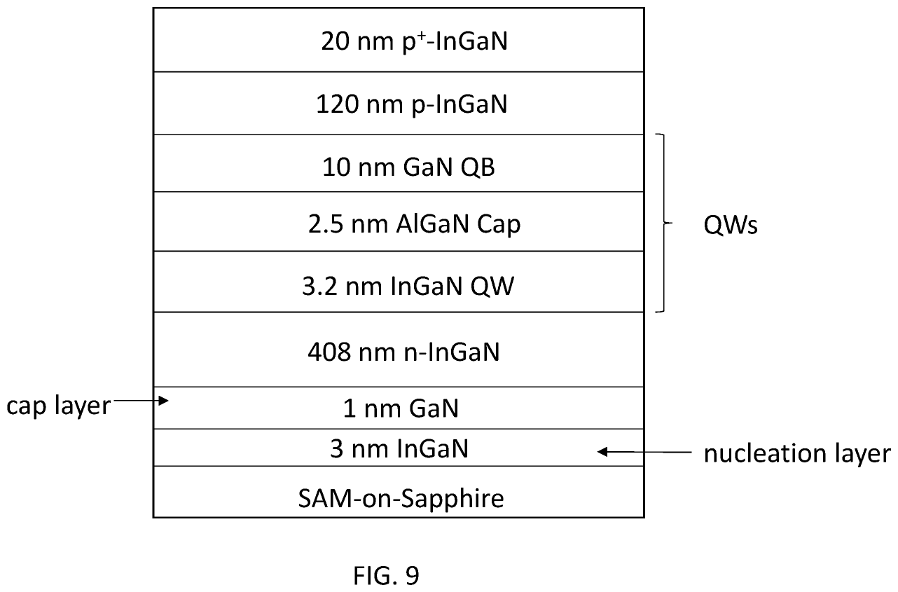

Based on these results, an LED was grown on an SAM-on-sapphire substrate, using the nucleation and cap layers. The LED heterostructure, including the layer thicknesses and materials, is shown schematically in FIG. 9.

In the LED, the n-InGaN layer was grown to a thickness of 408 nm. Next, an active region comprising three InGaN/AlGaN/GaN QWs was grown via MOCVD to target thicknesses of 3.2 nm/2.5 nm/10 nm, respectively. The AlGaN had an Al content of 10%, as measured by RSM. A 120 nm-thick layer of p-InGaN (Mg-doped InGaN) was grown on the active region, followed by the growth of a 20 nm-thick, heavily doped p-InGaN layer to form contacts for the LED. Bis (cyclopentadienyl) magnesium (Cp₂Mg) was used as the Mg precursor for p-doping the InGaN. The MOCVD growth conditions for the LED device layers were the same as those used in Shubhra S. Pasayat et al. 2021 Appl. Phys. Express 14 011004.

The LED successfully emitted blue electroluminescence with a peak emission wavelength of 515 nm at a current density of 1 A/cm².

### Example 2: LED Grown on GaN

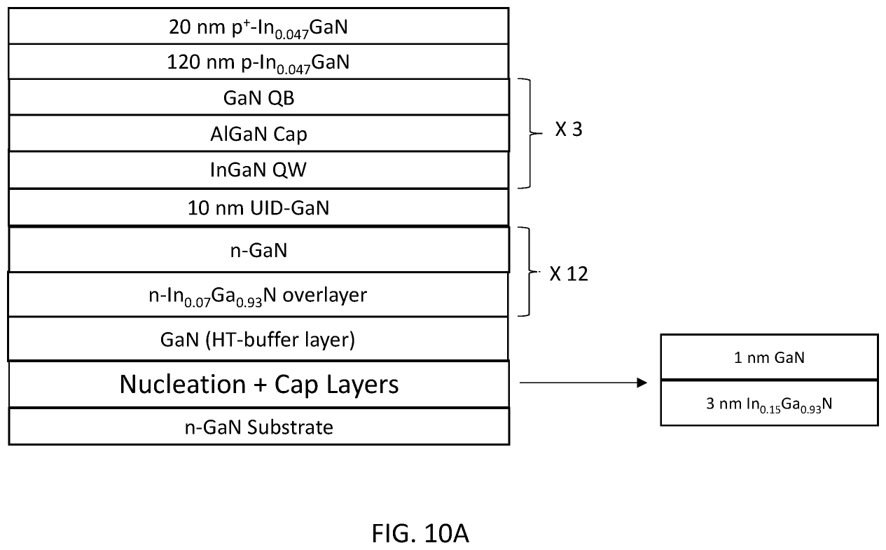

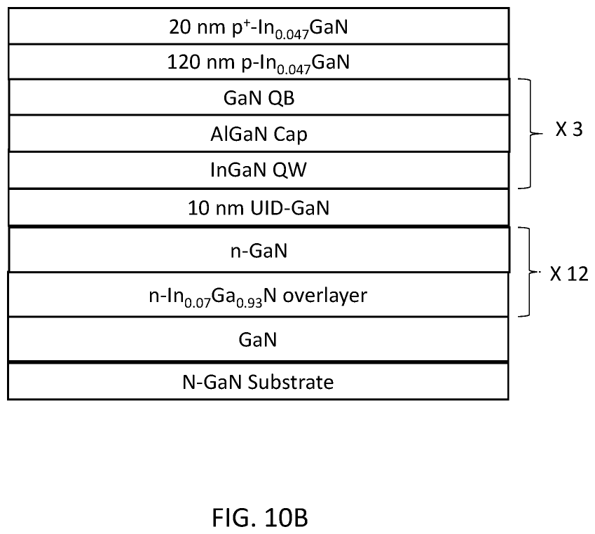

This example illustrates an LED in which the active layers, including an MQW structure, was MOCVD-grown on a heterostructure as shown in FIG. 10A. In this example, the substrate was n-doped GaN, rather than SAM. For comparison, an analogous MOCVD-grown LED having the same structure, but without the nucleation and cap layers, is shown in FIG. 10B. The emission results for both LEDs are shown in Table 1 for different current densities. As shown in the data, the inclusion of a nucleation layer (3 nm In_{0.15}Ga_{0.93}N and the cap layer (1 nm GaN) resulted in a longer wavelength without negatively impacting the light output poser.

TABLE 1

Current Density (A/cm²)

| | 1 | 2.5 | 5 | 10 |
|---|---|---|---|---|
| LED with Nucleation | 623 | 616 | 609 | 602 |
| and Cap Layers | | | | |
| LED without Nucleation | 639 | 638 | 627 | 620 |
| and Cap Layers | | | | |

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

If not already included, all numeric values of parameters in the present disclosure are proceeded by the term “about” which means approximately. This encompasses those variations inherent to the measurement of the relevant parameter as understood by those of ordinary skill in the art. This also encompasses the exact value of the disclosed numeric value and values that round to the disclosed numeric value.

What is claimed is:

1. A heterostructure comprising:
a substrate;
an In-containing group III-nitride nucleation layer having a thickness of 100 nm or less on the substrate;
a cap layer of AlₓIn_{y}Ga_{1-x-y}N, where 0≤x≤1, 0≤y≤1, 0≤z≤1, the cap layer having a thickness in the range from 1 nm to 100 nm on the In-containing group III-nitride nucleation layer; and
optionally, a group III-nitride overlayer over the cap layer.

2. The heterostructure of claim 1, wherein the In-containing group III-nitride of the nucleation layer is InₓGa₁₋ₓN, where 0<x≤1.

3. The heterostructure of claim 2, wherein the cap layer is a layer of GaN.

4. The heterostructure of claim 1, wherein the substrate comprises ScAlMgO₄, GaN, GaN-on-sapphire, ScAlMgO₄-on-sapphire, sapphire, AlN, AlN-on-sapphire, bulk ZnO, ZnO-on-sapphire, Si, SiC, or glass.

5. The heterostructure of claim 4, wherein the substrate comprises a sapphire sublayer and a ScAlMgO₄ overlayer, and the nucleation layer is on the ScAlMgO₄ overlayer.

6. The heterostructure of claim 3, wherein the substrate comprises ScAlMgO₄.

7. The heterostructure of claim 6, wherein the In-containing group III-nitride overlayer is InₓGa₁₋ₓN, wherein 0.15≤x≤0.20.

8. The heterostructure of claim 7, wherein the group III-nitride overlayer has an rms surface roughness of less than 30 nm over a 1 μm by 1 μm surface area.

9. The heterostructure of claim 1, wherein the substrate comprises GaN.

10. The heterostructure of claim 9, wherein the group III-nitride overlayer is InₓGa₁₋ₓN, where 0.05≤x≤0.15.

11. The heterostructure of claim 10, wherein the group III-nitride overlayer has an rms surface roughness of less than 30 nm over a 1 μm by 1 μm surface area.

12. The heterostructure of claim 1, wherein the substrate is a bulk sapphire substrate.

13. The heterostructure of claim 1, wherein the group III-nitride overlayer has a thickness of at least 50 nm.

14. The heterostructure of claim 1, wherein one or more of the In-containing group III-nitride nucleation layer, the cap layer, and the group III-nitride overlayer is p-doped or n-doped.

15. The heterostructure of claim 1, wherein the nucleation layer comprises two or more sublayers of In-containing group III-nitride, the sublayers having different compositions, different thicknesses, or both different compositions and thicknesses.

16. The heterostructure of claim 1, wherein the cap layer comprises two or more sublayers of AlₓIn_{y}Ga_{1-x-y}N, where 0≤x≤1, 0≤y≤1, 0≤z≤1, the sublayers having different compositions, different thicknesses, or both different compositions and thicknesses.

17. The heterostructure of claim 1, comprising the group III-nitride overlayer.

18. The heterostructure of claim 1, further comprising:
a buffer layer on the cap layer, the buffer layer having a same composition as the cap layer, but a lower density of dislocation defects than the cap layer; and
the group III-nitride overlayer on the buffer layer.

19. A light-emitting device comprising:
a heterostructure comprising:
a substrate;
an In-containing group III-nitride nucleation layer having a thickness of 100 nm or less on the substrate;
a cap layer of AlₓIn_{y}Ga_{1-x-y}N, where 0≤x≤1, 0≤y≤1, 0≤z≤1, the cap layer having a thickness in the range from 1 nm to 100 nm on the In-containing group III-nitride nucleation layer; and
an n-doped group III-nitride overlayer over the cap layer;
at least one active region comprising multiple quantum wells; and
a p-type doped group III-nitride layer, wherein the active region is disposed between the n-doped group III-nitride overlayer and the p-doped group III-nitride layer.

20. The light-emitting device of claim 19, wherein the group III-nitride overlayer is InₓGa₁₋ₓN, where 0<x≤1, and the light-emitting device is a light-emitting diode or a diode laser.

21. The light-emitting device of claim 19, wherein the light-emitting device is a light-emitting diode array comprising at least three light-emitting diodes formed over the cap layer, wherein the at least three light-emitting diodes have different emission spectra.

22. A method of making a heterostructure, the method comprising:
growing an In-containing group III-nitride nucleation layer having a thickness of 5 nm or less on a substrate at a temperature of 900° C. or lower via metal-organic chemical vapor deposition;
growing a cap layer of AlₓIn_{y}Ga_{1-x-y}N, where 0≤x≤1, 0≤y≤1, 0≤z≤1, having a thickness in the range from 1 nm to 5 nm on the In-containing group III-nitride nucleation layer via metal-organic chemical vapor deposition; and
optionally growing a buffer layer on the cap layer, at a higher temperature than the cap layer; and growing an In-containing group III-nitride overlayer on the cap layer or on the buffer layer.
